(19) United States
(12) Patent Application Publication
(10) Pub. No.: US 2025/0043879 A1
(43) Pub. Date: Feb. 6, 2025

(54) VALVE DEVICE, SUBSTRATE PROCESSING APPARATUS, METHOD OF MANUFACTURING VALVE DEVICE

(71) Applicant: Tokyo Electron Limited, Tokyo (JP)

(72) Inventor: Tsutomu HIROKI, Nirasaki City (JP)

(21) Appl. No.: 18/783,938

(22) Filed: Jul. 25, 2024

(30) Foreign Application Priority Data
Aug. 1, 2023 (JP) 2023-125355
Apr. 5, 2024 (JP) 2024-061387

(51) Int. Cl. F16K 27/02; F16K 25/02; F16K 49/00; H01L 21/67

(52) U.S. Cl. CPC F16K 27/0254; F16K 25/02; F16K 49/002; H01L 21/67017

(57) ABSTRACT

A valve device includes: a valve body configured to cause an opening through which a fluid passes to be in a closed state by moving close to the opening and cause the opening to be in an open state by moving away from the opening in the closed state; first and second extension/contraction portions configured to be extendible in a direction of a central axis of a first flow path according to movement of the valve body; an intermediate portion disposed between the first extension/contraction portion and the second extension/contraction portion; and a driver connected to the intermediate portion on an outside of the first extension/contraction portion and the second extension/contraction portion and configured to drive the valve body so as to move the valve body together with the intermediate portion in the direction between the open and the closed states.

### CROSS-REFERENCE TO RELATED APPLICATIONS

This application is based upon and claims the benefit of priority from Japanese Patent Application Nos. 2023-125355 and 2024-061387, filed on Aug. 1, 2023, and Apr. 5, 2024, respectively, the entire contents of which are incorporated herein by reference.

### TECHNICAL FIELD

The present disclosure relates to a valve device, a substrate processing apparatus, and a method of manufacturing the valve device.

### BACKGROUND

One process for manufacturing a semiconductor is a process of supplying a processing gas into a chamber in which a substrate is stored and forming a thin film on the substrate using plasma by depressurizing an interior of the chamber. A valve for opening and closing an exhaust path is installed on the exhaust path of the chamber used in this process as one means of controlling an internal pressure of the chamber (e.g., see Patent Document 1 and Patent Document 2). Both a valve disclosed in Patent Document 1 and a valve disclosed in Patent Document 2 open and close the exhaust path in such a manner that a valve body reciprocates. Further, in both the valve disclosed in Patent Document 1 and the valve disclosed in Patent Document 2, a cylinder serving as a driver that causes the valve body to reciprocate is disposed coaxially with the valve body.

### PRIOR ART DOCUMENT

### Patent Documents

Patent Document 1: Japanese Laid-Open Patent Publication No. 2008-069787
Patent Document 2: Japanese Laid-Open Patent Publication No. 2005-026516

### SUMMARY

According to one embodiment of the present disclosure, a valve device includes: a valve body configured to cause an opening through which a fluid passes to be in a closed state by moving close to the opening and cause the opening to be in an open state by moving away from the opening in the closed state; a first extension/contraction portion formed in a cylindrical shape and configured to be extendible in a direction of a central axis of a first flow path according to movement of the valve body, an inner side of the first extension/contraction portion functioning as the first flow path through which the fluid passes; a second extension/contraction portion disposed on one side of the first extension/contraction portion, formed in a cylindrical shape and configured to be extendible in the direction of the central axis of the first flow path according to the movement of the valve body, an inner side of the second extension/contraction portion functioning as the first flow path together with the first extension/contraction portion; an intermediate portion disposed between the first extension/contraction portion and the second extension/contraction portion and configured to support the valve body; and a driver connected to the intermediate portion on an outside of the first extension/contraction portion and the second extension/contraction portion and configured to drive the valve body so as to move the valve body together with the intermediate portion in the direction of the central axis of the first flow path and cause the opening to change between the open state and the closed state.

### BRIEF DESCRIPTION OF DRAWINGS

The accompanying drawings, which are incorporated in and constitute a portion of the specification, illustrate embodiments of the present disclosure, and together with the general description given above and the detailed description of the embodiments given below, serve to explain the principles of the present disclosure.

FIG. 1 is a perspective view illustrating a configuration example of a valve device according to a first embodiment.

FIG. 2 is a longitudinal cross-sectional perspective view illustrating the configuration example of the valve device illustrated in FIG. 1.

FIG. 3 is a perspective view illustrating an example of a discharge state of an inert gas.

FIG. 4 is a top view illustrating the example of the discharge state of the inert gas.

FIGS. 5A and 5B are schematic longitudinal cross-sectional views illustrating examples of an open state and a closed state of the valve device.

FIG. 6 is a perspective view illustrating a configuration example of an intermediate ring included in the valve device.

FIGS. 7A and 7B are simulations illustrating examples of a gas flow state for comparison.

FIG. 8 is a flowchart illustrating an example of a process of manufacturing the valve device.

FIG. 9 is a perspective view illustrating a configuration example of a valve device according to a second embodiment.

FIG. 10 is a diagram illustrating an example of a use state (third embodiment) of a valve device in a substrate processing apparatus.

FIG. 11 is a block diagram illustrating an example of a hardware configuration of the substrate processing apparatus illustrated in FIG. 10.

FIG. 12 is a diagram illustrating an example of a cross section taken along line A-A in FIG. 10.

FIG. 13 is an enlarged view illustrating an example of a region B surrounded by a circle of a dash-double-dotted line in FIG. 10.

FIG. 14 is an enlarged view illustrating an example of a region C surrounded by a circle of a dash-double-dotted line in FIG. 10.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In techniques of both Patent Document 1 and Patent Document 2 disclosed above, since the driver that causes the valve body to reciprocate is disposed coaxially with the valve, it is not possible to dispose the valve body and the driver apart from each other. This limits the number of locations at which the valve is disposed. Further, in the techniques of Patent Document 1 and Patent Document 2, a fluid flow direction on an upstream side and a fluid flow direction on a downstream side via the valve body are different from each other. That is, a fluid flowing from the upstream side of the valve body changes a direction on the downstream side of the valve body. Therefore, smooth passage of the fluid is obstructed and stagnation occurs. Particles contained in the fluid tend to accumulate in the stagnant fluid. The accumulated particles may adhere to, for example, the valve body.

Hereinafter, one embodiment of a technique according to the present disclosure will be described with reference to the drawings. However, a configuration described in this embodiment below is merely exemplary, and the present disclosure is not limited to this configuration. For example, each part included in this configuration may be replaced with any part that may perform the same function. In addition, an arbitrary component may be added. Further, any two or more configurations (features) of each embodiment may be combined.

### First Embodiment

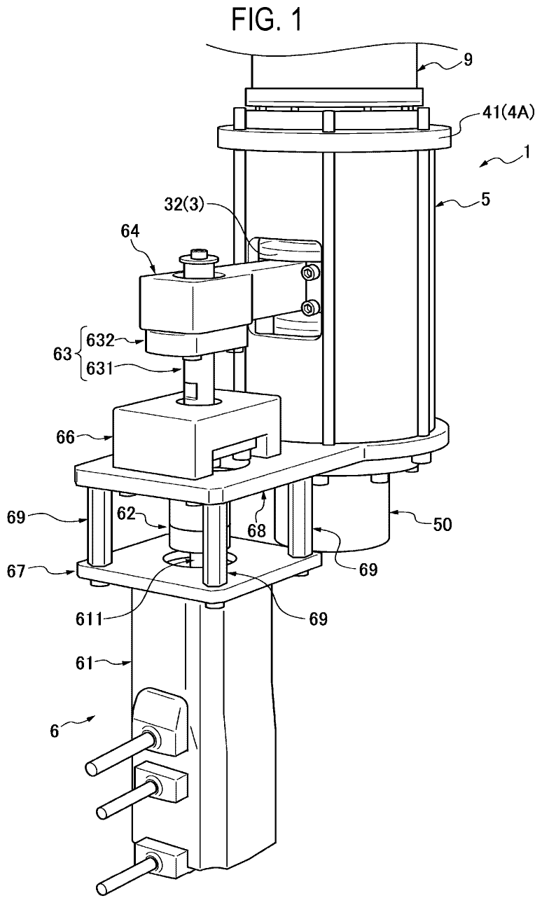

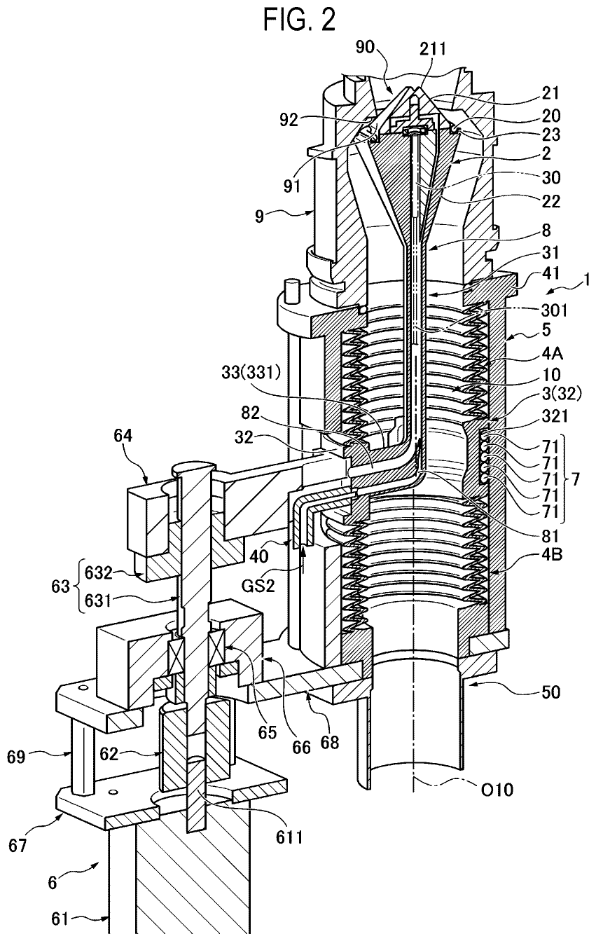

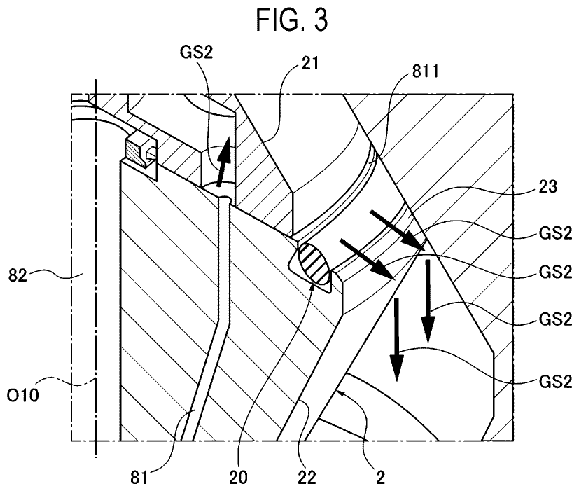

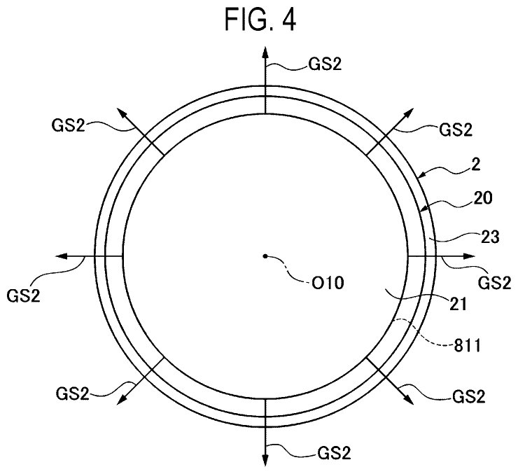

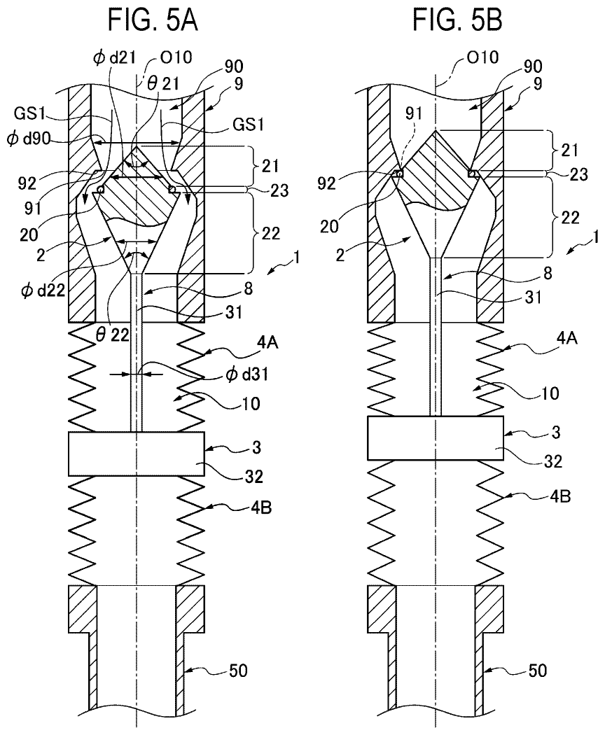

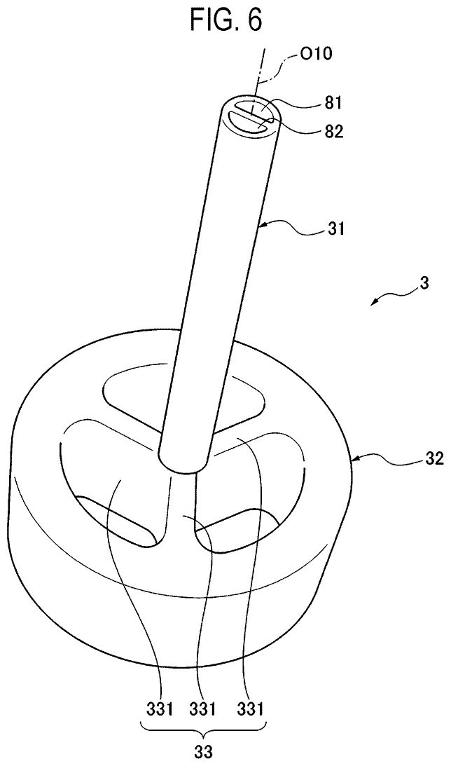

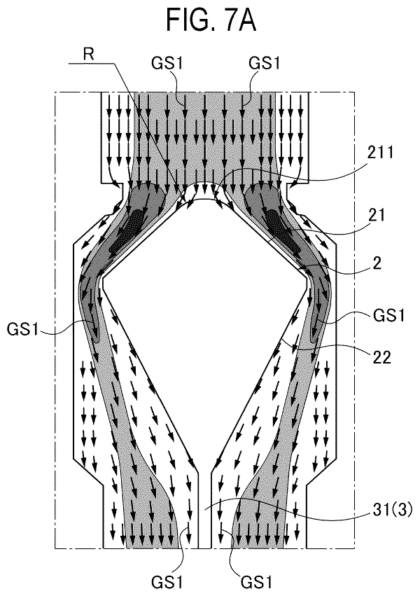

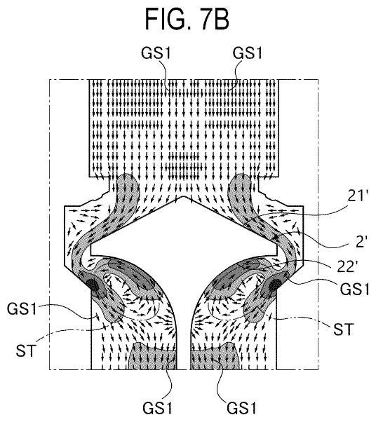

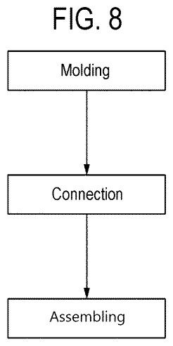

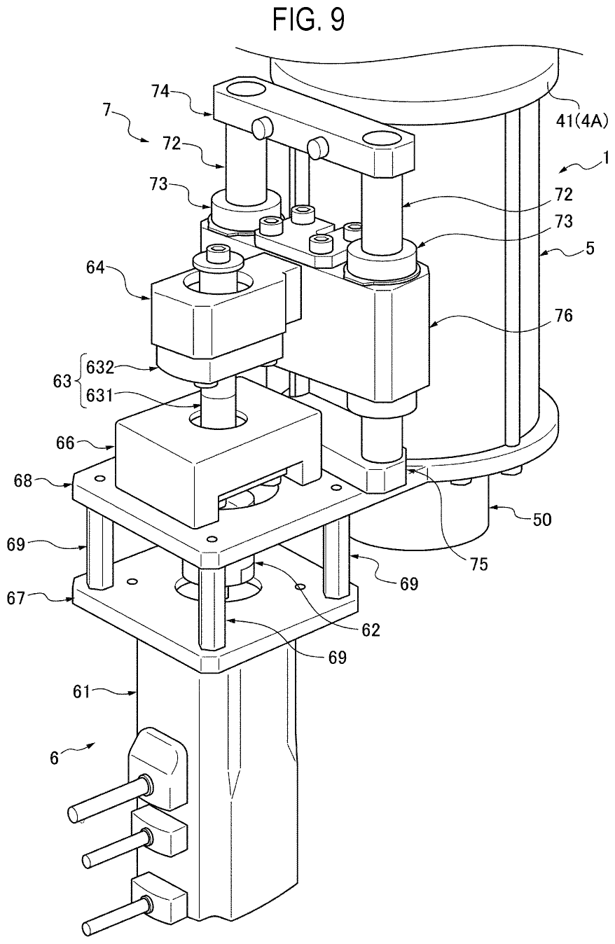

A first embodiment will be described below with reference to FIGS. 1 to 8. FIG. 1 is a perspective view illustrating a configuration example of a valve device according to a first embodiment. FIG. 2 is a longitudinal cross-sectional perspective view illustrating the configuration example of the valve device illustrated in FIG. 1. FIG. 3 is a perspective view illustrating an example of a discharge state of an inert gas. FIG. 4 is a top view illustrating the example of the discharge state of the inert gas. FIGS. 5A and 5B are schematic longitudinal cross-sectional views illustrating examples of an open state and a closed state of the valve device. FIG. 5A illustrates the open state of the valve device, and FIG. 5B illustrates the closed state of the valve device. FIG. 6 is a perspective view illustrating a configuration example of an intermediate ring included in the valve device. FIGS. 7A and 7B are simulations illustrating examples of a gas flow state for comparison. FIG. 7A illustrates an example of a gas flow state to the valve device, and FIG. 7B illustrates a comparative example of a gas flow state. FIG. 8 is a flowchart illustrating an example of a process of manufacturing the valve device. Hereinafter, for the sake of convenience in description, an upper side and a lower side in FIGS. 1 to 3 and FIGS. 5A to 7B (FIGS. 9, 10, 13, and 14 as well) will be referred to as “above (or upward)” and “below (or downward)”, respectively.

A valve device 1 illustrated in FIGS. 1 and 2 is an apparatus attached to an exhauster 9 of a chamber (not illustrated) that is in a depressurized state. In the present embodiment, the chamber to which the valve device 1 is attached is, for example, a double chamber including an inner chamber in which a substrate (wafer) is stored when manufacturing a semiconductor and an outer chamber in which the inner chamber is stored. A processing gas is supplied into this chamber. Then, an interior of the chamber is depressurized and a thin film is formed on the substrate using plasma. The valve device 1 may control an internal pressure of the chamber by opening and closing the exhauster 9. The exhauster 9 is constituted with a tubular (cylindrical) member. An exhaust port (opening) 91 opened and closed by the valve device 1 is provided in the middle of the exhauster 9 in an axial direction. In an open state, the exhaust port 91 exhausts gas (fluid) GS1 (see FIG. 5A) from the interior of the chamber. A flow path 10 of a straight line shape through which the gas GS1 passes is formed on a downstream side of the exhaust port 91.

As illustrated in FIG. 2, the valve device 1 includes a valve body 2, a seal member 20, a heater 30, an intermediate member (intermediate portion) 3, a first extension/contraction portion (first bellows) 4A, a second extension/contraction portion (second bellows) 4B, an outer cylindrical body 5, a driver 6, and a guider 7.

The valve body 2 is movable in the direction of a central axis O10 of the flow path 10 by the driver 6. Thus, when the valve body 2 moves close to the exhaust port 91, the exhaust port 91 is brought into a closed state (see FIG. 5B). Further, when the valve body 2 moves away from the exhaust port 91 in the closed state, the exhaust port 91 is brought into an open state (see FIGS. 2 and 5A). A movement distance of the valve body 2 during transition from the closed state to the open state or from the open state to the closed state varies according to the usage of the valve device 1 or the shape of the valve body 2, but is preferably, for example, 5 mm or more and 50 mm or less, and more preferably 15 mm or more and 20 mm or less. Further, a separation distance of the valve body 2 with respect to the exhaust port 91 in the open state may be adjusted by the driver 6. Thus, an opening degree of the exhaust port 91 may be adjusted and a discharge amount (flow rate) of the gas GS1 may be adjusted. In this embodiment, the central axis O10 is parallel to a vertical direction.

The valve body 2 has a cylindrical shape disposed parallel to the central axis O10. The valve body 2 includes a first tapered portion 21 formed at an upper portion thereof, that is, formed on the side of the exhaust port 91, and a second tapered portion 22 formed at a lower portion thereof, that is, formed on an opposite side to the first tapered portion 21. As illustrated in FIG. 5A, the first tapered portion 21 is a portion having a tapered shape, an outer diameter φd21 of which gradually decreases toward an upper side. The second tapered portion 22 is a portion having a tapered shape, an outer diameter φd22 of which gradually decreases toward a lower side. A tapered angle θ22 of the second tapered portion 22 is smaller than a tapered angle θ21 of the first taper portion 21. Due to this magnitude relationship between the tapered angles (θ22<θ21) and the flow path 10 being formed in a straight line, as illustrated in FIG. 7A, the gas GS1 is prevented or suppressed from stagnating on a downstream side of the valve body 2 and generating a stagnation region ST, as compared with a state illustrated in FIG. 7B. Thus, the gas GS1 may smoothly pass through the flow path 10, and particles contained in the gas GS1 may be prevented and reduced from stagnating, staying in the stagnation region ST, and adhering to the valve body 2. It is also possible to suppress pressure loss on front and back sides the valve body 2, which further contributes to preventing particle retention. In addition, although a valve body 2′ in Comparative Example illustrated in FIG. 7B has a first tapered portion 21′ and a second tapered portion 22′, a tapered angle of the first tapered portion 21′ and an average tapered angle of the second tapered portion 22′ are almost the same. Further, “particles” are, for example, ones that are partially peeled off from a thin film formed on a substrate inside the chamber.

Preferably, a top portion 211 of the first tapered portion 21 is rounded. Thus, resistance to the gas GS1 at the first tapered portion 21 may be reduced, which ensures a smooth flow of the gas GS1. A radius R (see FIG. 7A) when the top portion 211 is rounded varies according to the size of the valve body 2, and the like, but is preferably, for example, 3 mm or more and 20 mm or less, and more preferably 7 mm or more and 12 mm or less. As illustrated in FIGS. 5A and 5B, the exhauster 9 is provided with a flow path (another flow path) 90 on an upstream side of the exhaust port 91. The flow path 90 is formed in a straight line like the flow path 10 and is disposed on the central axis O10 of the flow path 10. The flow path 90 has a tapered shape in which an inner diameter φd90 gradually increases toward an upper side. A portion of the first tapered portion 21 enters the flow path 90 (exhaust port 91) that is in either the closed state or the open state. Thus, for example, excessive discharge of the gas GS1 from the exhaust port 91 in the open state may be suppressed.

A maximum of the outer diameter φd21 of the first tapered portion 21 and a maximum of the outer diameter φd22 of the second tapered portion 22 are different from each other. In this embodiment, the maximum of the outer diameter φd21 of the first tapered portion 21 is smaller than the maximum of the outer diameter φd22 of the second tapered portion 22. Thus, a stepped portion 23 is formed between the first tapered portion 21 and the second tapered portion 22. The seal member 20 is provided in the stepped portion 23. The seal member 20 has a ring shape in a circumferential direction of the valve body 2 and is fitted and fixed to the valve body 2. A constituent material of the seal member 20 is not particularly limited and may use, for example, a heat-resistant elastic material such as polyimide. Further, a flat surface 92 that faces the seal member 20 and is perpendicular to the central axis O10, that is, has the central axis O10 as a normal line, is formed at an edge of the exhaust port 91. The seal member 20 is in close contact with the flat surface 92 in the closed state. Thus, the flow of the gas GS1 may be certainly blocked, that is, the discharge of the gas GS1 from the exhaust port 91 may be certainly stopped. Here, it is assumed that, instead of the flat surface 92, an inclined surface which is inclined with respect to the central axis O10 is formed at the edge of the exhaust port 91. In this case, the seal member 20 may be in close contact with the inclined surface when the exhaust port 91 is in the closed state, but force that causes the seal member 20 to twist (rotate) is generated from the inclined surface. This twist may deteriorate the seal member 20 and may cause a decrease in adhesion (durability) in the closed state. In the present embodiment, it is possible to prevent the force that causes the twist from acting on the seal member 20, and therefore, the close contact between the seal member 20 and the flat surface 92 in the closed state may be maintained for a long time.

The valve body 2 has the first tapered portion 21 and the second tapered portion 22 that are configured as separate bodies. These separate bodies are connected to each other by, for example, screw(s).

As illustrated in FIG. 2, an intermediate member 3 is disposed on a downstream side of the valve body 2. The intermediate member 3 includes a supporter 31 that supports the valve body 2, a ring-shaped (circular) ring part 32 centered on the central axis O10, and a connector 33 that connects the ring part 32 and the supporter 31. The supporter 31 extends in a rod shape in the direction of the central axis O10. An upper end of the supporter 31 is connected to a lower end of the second tapered portion 22. In this way, the valve body 2 may be supported. An outer diameter φd31 of the supporter 31 is constant in the direction of the central axis O10. In this embodiment, the outer diameter φd31 of the supporter 31 is the same as a minimum of the outer diameter φd22 of the second tapered portion 22 (see FIG. 5A). Thus, the valve body 2 may be stably supported while making a thickness of the support 31 as small as possible. Further, the proportion of the supporter 31 in the flow path 10 may be suppressed, which makes it possible to smoothly pass the gas GS1 through the flow path 10. The supporter 31 is disposed at the center of the ring part 32. Thus, the support 31 is disposed on the central axis O10.

As illustrated in FIG. 6, the connector 33 has a plurality of connection pieces 331 disposed in a radial shape centered on the supporter 31. Each connection piece 331 connects an outer circumferential portion of a lower end of the supporter 31 and an inner circumferential portion of the ring part 32. The gas GS1 may pass between the connection pieces 331 toward a downstream side. Although the number of the connection pieces 331 is three in the configuration illustrated in FIG. 6, the number of the connection pieces 331 is not limited to three and may be, for example, two or more than four. Further, decreasing the number of the connection pieces 331 improves passage of the gas GS1.

As will be described later, the second tapered portion 22 of the valve body 2 and the intermediate member 3 are constituted with a molded body 8 that is integrally molded by an additive manufacturing method in a molding operation. Constituent materials of the valve body 2 and the intermediate member 3 are not particularly limited and are preferably, for example, metal materials such as SUS316.

As illustrated in FIG. 2, an inert gas flow path 81 through which an inert gas GS2 passes is provided inside the molded body 8, that is, inside the valve body 2 and the intermediate member 3. The inert gas flow path 81 extends from the ring part 32 of the intermediate member 3 to the first tapered portion 21 sequentially via one connector 33, the supporter 31, and the second tapered portion 22 of the valve body 2. As illustrated in FIGS. 3 and 4, the inert gas flow path 81 includes a discharge port 811 through which the inert gas GS2 is discharged into the flow path 10. The discharge port 811 is provided on an upper side of the valve body 2 (in the present embodiment, at a boundary between the first tapered portion 21 and the second tapered portion 22). Further, the discharge port 811 is constituted with slits formed over the entire circumference of the valve body 2. As a result, the inert gas GS2 is discharged radially from the discharge port 811.

As described above, the seal member 20 is provided between the first tapered portion 21 and the second tapered portion 22, that is, in the stepped portion 23. When the inert gas GS2 is discharged radially from the discharge port 811, the inert gas GS2 is brought into contact with the seal member 20 from the inside to the outside over the entire circumference of the seal member 20. Thus, even if particles adhere to the seal member 20, they may be blown away by the inert gas GS2. Further, the gas GS1 inside the flow path 10 may be diluted with the inert gas GS2. Thus, it is possible to prevent particles from adhering to the first extension/contraction portion 4A or the second extension/contraction portion 4B which is on a downstream side of the valve body 2.

Further, a joint 40 that communicates with the inert gas flow path 81 is connected to an outer peripheral portion of the ring part 32 of the intermediate member 3. A supplier (not illustrated) for supplying the inert gas GS2 is connected to an upstream side of the joint 40, that is, an opposite side to the ring part 32. Thus, the inert gas GS2 may be supplied from the supplier to the inert gas flow path 81. The inert gas GS2 is not particularly limited and may be, for example, a nitrogen gas.

As illustrated in FIG. 2, a storage (wiring storage) 82 that stores a heater 30 is provided inside the molded body 8 in which the heater 30 is housed. The storage 82 extends from the ring part 32 of the intermediate member 3 to the second tapered portion 22 of the valve body 2 sequentially via one connector 33 and the supporter 31. In this embodiment, the storage 82 is disposed parallel to the inert gas flow path 81. The heater 30 generates heat by being supplied with electric power and may use, for example, a ceramic heater or the like. The heat from the heater 30 contributes to prevent particles from adhering to the valve body 2. Further, an electric power wiring (cable) 301 is connected to the heater 30. The storage 82 may store the heater 30 together with the electric power wiring 301. Thus, the electric power wiring 301 may be prevented from being exposed inside the flow path 10. By preventing this exposure, it is possible to prevent the electric power wiring 301 from rubbing against the interior of the flow path 10 and being cut inside the flow path 10 when the valve body 2 moves. The electric power wiring 301 is connected to a controller (not illustrated) that controls the operation of the heater 30.

As illustrated in FIG. 2, the first extension/contraction portion 4A and the second extension/contraction portion 4B are disposed in the direction of the central axis O10 via the ring part 32 of the intermediate member 3. In this embodiment, the first extension/contraction portion 4A is disposed above the ring part 32, and the second extension/contraction portion 4B is disposed below the ring part 32. Each of the first extension/contraction portion 4A and the second extension/contraction portion 4B is formed of a cylindrical member. An interior of each of the first extension/contraction portion 4A and the second extension/contraction portion 4B functions as the flow path 10 through which the gas GS1 passes. As a result, the flow path 10 has a straight shape and the gas GS1 may smoothly pass through the flow path 10, which makes it possible to prevent the occurrence of stagnation and adhesion of particles.

Each of the first extension/contraction portion 4A and the second extension/contraction portion 4B has a bellows shape. Thus, each of the first extension/contraction portion 4A and the second extension/contraction portion 4B is extendible in the direction of the central axis O10 according to movement of the valve body 2. As illustrated in FIG. 5A, when the valve body 2 moves upward such that the closed state is established, the first extension/contraction portion 4A contracts and the second extension/contraction portion 4B extends. Further, as illustrated in FIG. 5B, when the valve body 2 moves downward such that the open state is established, the first extension/contraction portion 4A extends and the second extension/contraction portion 4B contracts.

Further, a flange 41 having an enlarged outer diameter is formed at an upper end of the first extension/contraction portion 4A. The flange 41 is fixed to the exhauster 9. A communication pipe 50 that communicates with the second extension/contraction portion 4B and is disposed in the direction of the central axis O10, is connected to a lower end of the second extension/contraction portion 4B. The communication pipe 50 functions as a portion of the flow path 10 and may discharge the gas GS1 together with particles to the outside of the valve device 1. It is desirable that an average inner diameter of the first extension/contraction portion 4A, an average inner diameter of the second extension/contraction portion 4B, and an inner diameter of the communication pipe 50 are substantially the same. This contributes to smooth passage of the gas GS1 inside the flow path 10.

The first extension/contraction portion 4A and the second extension/contraction portion 4B are made of the same metal material. The metal material is not particularly limited. For example, a flexible metal material such as Hastelloy may be used for the first extension/contraction portion 4A and the second extension/contraction portion 4B. Thus, each of the first extension/contraction portion 4A and the second extension/contraction portion 4B may easily extend and contract. As mentioned above, SUS316 may be used as the constituent material of the intermediate member 3. In this case, the constituent material of the intermediate member 3, and the constituent materials of the first extension/contraction portion 4A and the second extension/contraction portion 4B are different metal materials. In this embodiment, a lower end of the first extension/contraction portion 4A and an upper end of the ring part 32 of the intermediate member 3 are connected to each other by welding. Further, an upper end of the second extension/contraction portion 4B and a lower end of the ring part 32 of the intermediate member 3 are also connected to each other by the welding. With such connections, the first extension/contraction portion 4A and the second extension/contraction portion 4B may extend and contract as the valve body 2 moves.

As illustrated in FIG. 2, the first extension/contraction portion 4A, the second extension/contraction portion 4B, and the intermediate member 3 are stored in an outer cylindrical body 5. An upper end of the outer cylindrical body 5 is fixed to the flange 41 of the first extension/contraction portion 4A, and a lower end thereof is fixed to the lower end of the second extension/contraction portion 4B via a fixing member 68 of the driver 6. The interior of the outer cylindrical body 5 is in a vacuum state. Thus, a heat insulating effect for the flow path 10 is obtained. The outer cylindrical body 5 may be omitted depending on a usage state of the valve device 1.

A guider 7 is disposed inside the outer cylindrical body 5. The guider 7 guides the valve body 2 when the valve body 2 moves. The guider 7 has a plurality of spheres 71 disposed between the outer peripheral portion of the ring part 32 of the intermediate member 3 and an inner peripheral portion of the outer cylindrical body 5. In this embodiment, five spheres 71 disposed in a row in the direction of the central axis O10 form one set. Herein, at least three sets are disposed at equal intervals around the central axis O10. Thus, each sphere 71 rolls as the valve body 2 moves so that the valve body 2 may be stably guided on the central axis O10. The number of the spheres 71 in each set is not limited to five. Further, a groove 321 in which the spheres 71 of each set are stored is formed in the outer peripheral portion of the ring part 32. This makes it possible to prevent misalignment of the positions of the spheres 71 of each set. Further, in this embodiment, it is desirable to adjust a depth of the groove 321 by interposing a thin plate-like shim between the spheres 71 in the groove 321. This may prevent each sphere 71 from spinning idly or, vice versa, from not rotating, when the valve body 2 moves.

As illustrated in FIGS. 1 and 2, the driver 6 is disposed on an outer side of the outer cylindrical body 5 (the first extension/contraction portion 4A and the second extension/contraction portion 4B). The driver 6 drives the valve body 2 so as to be movable in the direction of the central axis O10 and cause the opening to change between the open state and the closed state. The driver 6 includes a motor 61, a coupling 62, a ball screw 63, a connection member 64, a bearing 65, a bearing storage 66, a motor supporter 67, the fixing member 68, and a column member 69.

The motor 61 is supported by the motor supporter 67 in a state in which a rotary shaft 611 of a rotor (not illustrated) is oriented vertically upward. The motor 61 is not particularly limited and may be, for example, a servo motor. The ball screw 63 includes a screw shaft 631 and a nut 632 screwed into the screw shaft 631. The screw shaft 631 and the rotary shaft 611 of the motor 61 are connected to each other via the coupling 62. Further, the screw shaft 631 is rotatably supported by the bearing 65 stored in the bearing storage 66. The nut 632 is connected to the ring part 32 of the intermediate member 3 via the connection member 64 of a beam shape. The connection member 64 is fixed to the ring part 32 while rotatably supporting the nut 632. The fixing member 68 has a plate shape, and one end thereof is fixed to the lower end of the second extension portion 4B. The bearing storage 66 is fixed to an upper side of the other end of the fixing member 68. The motor supporter 67 is connected to a lower side of the other end of the fixing member 68 via a plurality of column members 69.

In the driver 6 having such a configuration, when the motor 61 is driven to rotate the rotary shaft 611, rotational force generated at this time is transmitted to the screw shaft 631 via the coupling 62. As a result, the screw shaft 631 rotates and the nut 632 rises, for example. Since the nut 632 is connected to the intermediate member 3 via the connection member 64, the nut 632 rises together with the intermediate member 3. Thus, the valve body 2 may be raised together with the intermediate member 3, so that the valve body 2 may be in the closed state. Further, from this state, the motor 61 is driven and the rotary shaft 611 is rotated in the opposite direction to the above direction, so that the rotational force is transmitted to the screw shaft 631 via the coupling 62. As a result, the screw shaft 631 rotates, and the nut 632 is lowered together with the intermediate member 3. Thus, the valve body 2 may be lowered together with the intermediate member 3 and may be in the open state. Further, since the driver 6 is configured to include the motor 61 and the ball screw 63, a separation distance of the valve body 2 with respect to the exhaust port 91 may be accurately adjusted in the open state. Thus, an opening degree of the exhaust port 91 is adjusted so that a discharge amount of the gas GS1 may be adjusted. Further, compared to the case in which the driver 6 is configured to include, for example, an air cylinder, it is possible to eliminate impact when the seal member 20 collides with the flat surface 92 in the closed state. Since impact in the seal member 20 leads to deterioration of durability or the like, such an impact elimination is desirable from the viewpoint of suppressing the deterioration.

In the valve device 1 configured as described above, the driver 6 that causes the valve body 2 to reciprocate is disposed on the outside of the valve device 1. Thus, the valve body 2 and the driver 6 may be disposed to be spaced apart from each other. Therefore, a structure including the valve body 2, the seal member 20, the heater 30, the intermediate member 3, and the first extension/contraction portion 4A, the second extension/contraction portion 4B, the outer cylindrical body 5, and the guider 7, excluding the driver 6, may be miniaturized. This increases a degree of freedom in layout when disposing the valve device 1, which makes it possible to dispose the valve device 1 as close as possible to, for example, the exhauster 9. Such an arrangement is desirable from the viewpoint of reducing the loss of the gas GS1 discharged from the exhauster 9 and reducing volume of the gas GS1. In addition, the valve device 1 has a simple configuration in which the flow path 10 is linear and the valve body 2 reciprocates along the flow path 10, thereby allowing the gas GS1 to pass smoothly and reducing the adhesion of particles to the valve body 2. Further, the valve device 1 may be easily separated from the exhauster 9 by releasing fixation between the first extension/contraction portion 4A and the exhauster 9. Thus, for example, the seal member 20 may be easily replaced. Then, by fixing the first extension/contraction portion 4A to the exhauster 9 again and attaching the valve device 1 to the exhauster 9, the valve device 1 may be used continuously.

Next, a method of manufacturing the valve device 1 will be described with reference to FIG. 8. As illustrated in FIG. 8, the method of manufacturing the valve device includes a molding operation, a connection operation, and an assembling operation. These operations are sequentially performed. In the method of manufacturing the valve device, an arbitrary operation may be performed between the operations as necessary.

In the molding operation, the molded body 8 is obtained by integrally molding the second tapered portion 22 of the valve body 2 and the intermediate member 3 by additive manufacturing. For example, a 3D printer or the like may be used for the additive manufacturing method. Thus, the molded body 8 of the second tapered portion 22 of the valve body 2 and the intermediate member 3 may be molded quickly and easily. Then, the first tapered portion 21 of the valve body 2 prepared in advance is connected to the molded body 8 by, for example, screw fixation.

In the connection operation, the first extension/contraction portion 4A and the second extension/contraction portion 4B are prepared in advance. Then, an upper end of the ring part 32 of the molded body 8 (intermediate member 3) formed in the molding operation and a lower end of the first extension/contraction portion 4A are connected to each other. Further, a lower end portion of the ring part 32 and an upper end of the second extension/contraction portion 4B are connected to each other. Each connection method is not particularly limited and may use, for example, a connection method by welding.

In the assembling operation, the outer cylindrical body 5, the driver 6, and the guider 7 are prepared in advance. Then, these components, and connection bodies of the molded body 8, the first extension/contraction portion 4A and the second extension/contraction portion 4B connected in the connection operation, are assembled with each other. As a result, the valve device 1 may be obtained.

### Second Embodiment

A second embodiment will be described below with reference to FIG. 9. However, a description of the second embodiment will focus on differences from the embodiment described above, and redundant descriptions thereof will be omitted. The second embodiment is identical to the first embodiment except that the configuration of the guider 7 is different. FIG. 9 is a perspective view illustrating a configuration example of a valve device according to the second embodiment. As illustrated in FIG. 9, in this embodiment, the guider 7 is fixed to the fixing member 68 of the driver 6 on the outside of the outer cylindrical body 5. In this embodiment, the guider 7 does not include the spheres 71 and has a configuration described below instead of the spheres 71. The guider 7 includes two linear shafts 72, two linear bushes 73, a first connection member 74, a second connection member 75, and a third connection member 76.

Each linear shaft 72 is disposed parallel to the ball screw 63 of the driver 6. Further, the connection member 64 of the driver 6 is disposed between the linear shafts 72. The linear bushes 73 are disposed on the linear shafts 72 one by one. The linear bushes 73 slide (move) on the linear shafts 72. The first connection member 74 connects upper ends of the linear shafts 72 to each other, and the second connection member 75 connects lower ends of the linear shafts 72 to each other. This allows each linear shaft 72 to be maintained parallel to the ball screw 63. The third connection member 76 connects the linear bushes 73 to each other. Further, the connection member 64 of the driver 6 is also connected to the third connection member 76. In addition to the connection member 64, the third connection member 76 may move up and down together with the linear bushes 73. The guider 7 having such a configuration may guide the valve body 2 in a stable manner. Further, since the guider 7 of this embodiment is disposed on the outside, the guider 7 may be applied at a temperature (e.g., 320 degrees C.) higher than that of the guider 7 of the first embodiment.

Each of the number of the linear shafts 72 and the number of the linear bushes 73 is two in this embodiment, but is not limited thereto and may be, for example, one.

### Third Embodiment

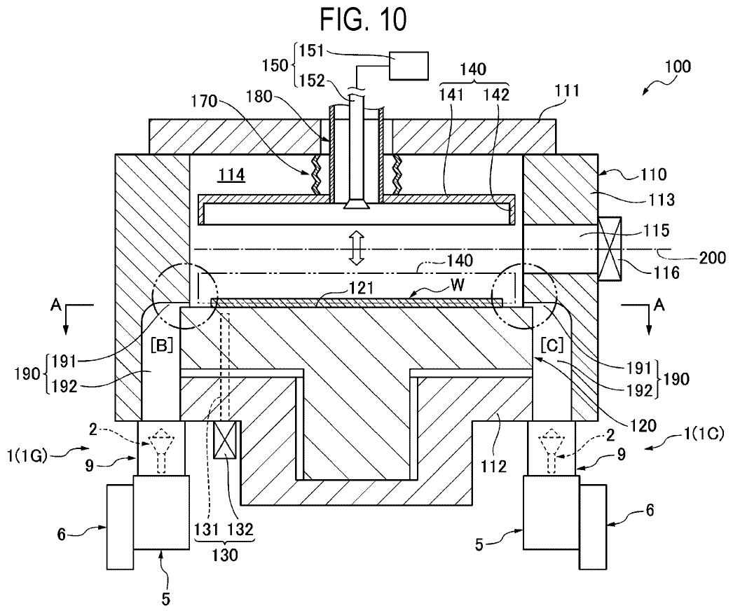

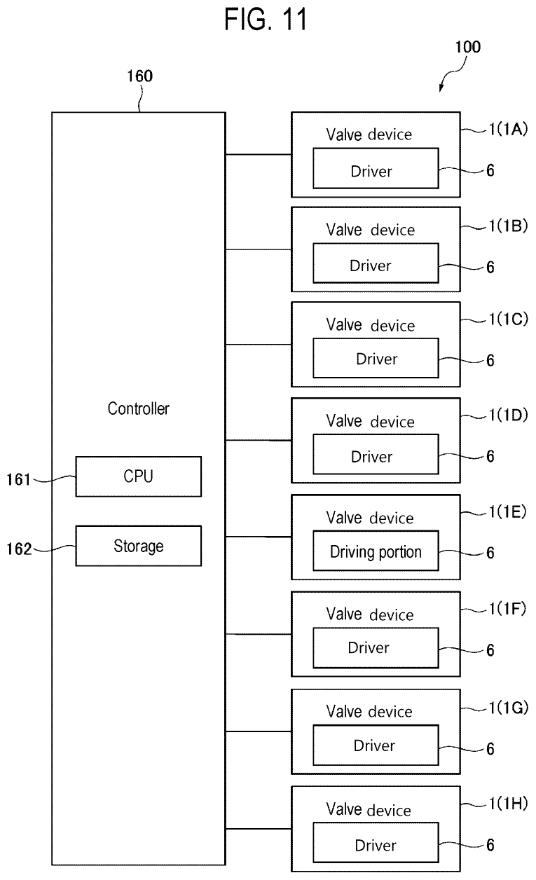

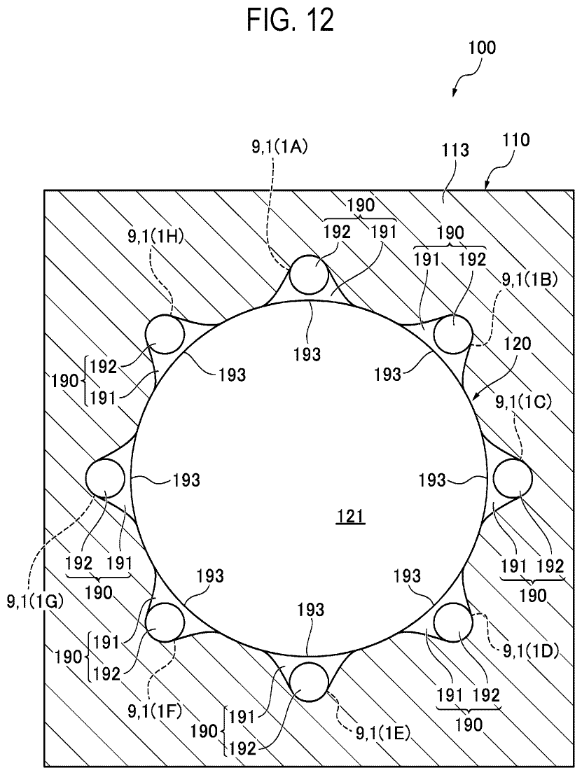

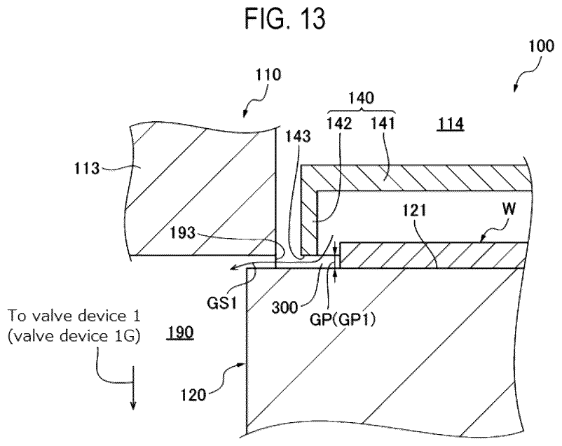

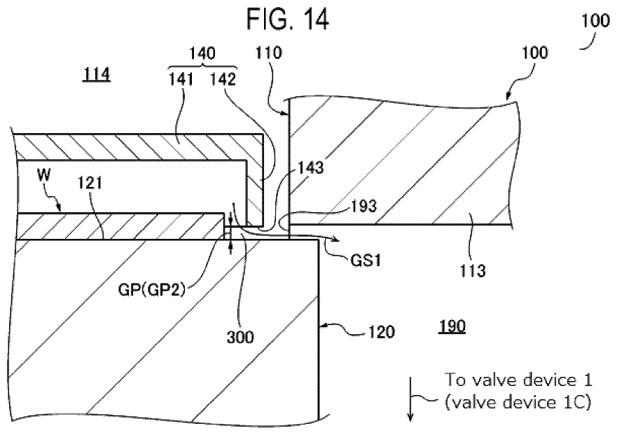

A third embodiment will be described below with reference to FIGS. 10 to 14, focusing on differences from the above-described embodiments, and redundant descriptions thereof will be omitted. FIG. 10 is a diagram illustrating an example of a use state (third embodiment) of a valve device in a substrate processing apparatus. FIG. 11 is a block diagram illustrating an example of a hardware configuration of the substrate processing apparatus illustrated in FIG. 10. FIG. 12 is a diagram illustrating an example of a cross section taken along line A-A in FIG. 10. FIG. 13 is an enlarged view illustrating an example of a region B surrounded by a circle of a dash-double-dotted line in FIG. 10. FIG. 14 is an enlarged view illustrating an example of a region C surrounded by a circle of a dash-double-dotted line in FIG. 10.

A substrate processing apparatus 100 illustrated in FIG. 10 is an apparatus that performs processing on a substrate. In this embodiment, the substrate is a wafer W used in manufacturing a semiconductor. The substrate processing apparatus 100 is an apparatus that forms a thin film on the wafer W. The substrate processing apparatus 100 includes a chamber 110, a placement table (stage) 120, a lifter 130, an exhauster 9, a valve device 1, a cover member 140, and a gas supplier 150. Further, as illustrated in FIG. 11, the substrate processing apparatus 100 includes a controller 160 that controls the driver 6 of the valve device 1. In addition to the driver 6, for example, the heater 30 may be included in objects to be controlled by the controller 160.

As illustrated in FIG. 10, the chamber 110 is configured as a cylindrical body including a ceiling portion 111 disposed at the top thereof, a bottom portion 112 disposed at the bottom thereof, and a sidewall portion 113 disposed between the ceiling portion 111 and the bottom portion 112. An interior of the chamber 110 is a processing space 114 in which the wafer W is processed. The sidewall portion 113 is provided with a loading/unloading port 115 through which the wafer W is loaded and unloaded in a horizontal direction (a left and right direction in FIG. 10), and a gate valve 116 for opening/closing the loading/unloading port 115.

The stage 120 is stored in the processing space 114 (the chamber 110). The stage 120 is fixed to the bottom portion 112 of the chamber 110. The stage 120 has a placement surface 121 on which the wafer W is placed. The placement surface 121 is circular and has a horizontal plane. When loading the wafer W into the processing space 114, first, the gate valve 116 is open. Subsequently, the wafer W is loaded into the processing space U in the horizontal direction from the loading/unloading port 115 by a transfer arm (not illustrated) that loads and unloads the wafer W. Thereafter, the wafer W is placed on the placement surface 121 of the stage 120. Subsequently, the transfer arm retreats from the processing space U, and the gate valve 116 is closed. In this way, a process of forming a thin film on the wafer W inside the processing space 114 is performed. After such a thin film forming processing, the wafer W is unloaded from the processing space 114. During this unloading, first, the gate valve 116 is open. Subsequently, the wafer W is unloaded from the processing space U by the transfer arm by passing through the loading/unloading port 115 in the horizontal direction. Thereafter, the gate valve 116 is closed. Although the stage 120 is fixed to the chamber 110 in this embodiment, the stage 120 is not limited thereto and may be configured to be movable in an up and down direction (vertical direction), for example, with respect to the chamber 110. Hereinafter, a path through which the wafer W passes via the loading/unloading port 115 and is loaded/unloaded in the horizontal direction, that is, a path along which the wafer W is transferred, will be referred to as a “transfer path 200.”

The lifter 130 includes a lifter pin (elevating pin) 131 that moves from the bottom portion 112 of the chamber 110 to the stage 120, and a pin driver 132 that is fixed to the bottom portion 112 of the chamber 110 and drives the lifter pin 131 in a vertical direction. The lifter pin 131 may take a protruding state in which the lifer pin 131 protrudes upward from the placement surface 121 of the stage 120 and a retracted state in which the lifter pin 131 is located below the placement surface 121 by the pin driver 132. A plurality of lifters 130 is disposed at equal intervals in a circumferential direction of the placement surface 121 when viewed from a direction facing the placement surface 121, that is, when viewing the placement surface 121 from above. The number of the lifters 130 is preferably, for example, three, but is not limited thereto.

The lifter 130 described above is used when loading the wafer W into the processing space 114 or when unloading the wafer W from the processing space 114. When loading the wafer W into the processing space 114, each lifter pin 131 is in the protruding state, and the transfer arm may support the wafer W on each lifter pin 131 in the protruding state. Then, the lifter pins 131 descend until the lifter pins 131 are in the retracted state while supporting the wafer W. In this way, the thin film may be formed on the wafer W on the placement surface 121. Further, when the wafer W subjected to the thin film forming process is unloaded from the processing space 114, each lifter pin 131 is set to the protruding state again, and the wafer W is supported on each lifter pin 131 in the protruding state. In this way, the wafer W may be unloaded by the transfer arm.

The exhauster 9 is connected to a lower portion of the sidewall portion 113 of the chamber 110. The exhauster 9 communicates with the processing space 114 and may exhaust the interior of the chamber 110. As described above, the exhauster 9 is constituted with a tubular (cylindrical) member, and a central axis thereof is parallel to the vertical direction. As illustrated in FIG. 12, a plurality of exhausters 9 is disposed at equal intervals in a circumferential direction of the placement surface 121 when viewed the placement surface 121 from above. Although the number of exhausters 9 is eight in this embodiment, the number of exhausters 9 is not limited thereto and may be at least one.

The valve device 1 that opens and closes the exhauster 9 is connected to each exhauster 9. Hereinafter, as illustrated in FIG. 12, the valve device 1 connected to the uppermost exhauster 9 will be referred to as a “valve device 1A”. In addition, the valve devices 1 disposed clockwise from the valve device 1A are sequentially referred to as “valve device 1B”, “valve device 1C”, “valve device ID”, “valve device 1E”, “valve device IF”, “valve device 1G”, and “valve device 1H”. As described above, the valve device 1 is an apparatus that opens and closes the exhauster 9 to control the internal pressure of the processing space 114. As the valve device 1, the valve device according to the first embodiment is used. In the substrate processing apparatus 100, the valve device 1 of the second embodiment may also be used instead of the valve device 1 of the first embodiment.

The gas supplier 150 supplies a processing gas for the thin film formation processing to the wafer W. The gas supplier 150 includes a gas source 151 for storing the processing gas and a gas supply pipe 152 connected to the gas source 151 to supply the processing gas.

As illustrated in FIG. 10, a cover member 140 is provided in the chamber 110 so as to be movable in the vertical direction by a cover member driver (not illustrated). Due to this movement, the cover member 140 may take a first state (see the cover member 140 indicated by a dash-double-dotted line) in which the cover member 140 covers the wafer W placed on the placement surface 121, and a second state in which the cover member 140 opens the wafer W from the first state. The cover member 140 is located below the transfer path 200 in the first state and is located above the transfer path 200 in the second state. Thus, the transfer path 200 may be secured to a degree such that the transfer arm may sufficiently pass through.

The cover member 140 includes a disc portion 141 of a disc shape and a ring part 142 that is formed in a ring shape along an edge of the disc portion 14 and protrudes downward. The disc portion 141 is supported by the ceiling portion 111 of the chamber 110 via a supporter 170. The supporter 170 is formed in a cylindrical bellows that is extendible as the cover member 140 moves up and down. Further, a cylindrical portion 180 that is connected to the disc portion 141 and through which the gas supply pipe 152 is inserted is disposed concentrically with the supporter 170 inside the supporter 170. The ring part 142 surrounds the wafer W in the first state. In this state, the processing gas from the gas supply pipe 152 is supplied to the wafer W located inside the cover member 140.

As illustrated in FIGS. 13 and 14, a gap 300 is formed between a lower surface 143 of the ring part 142 and the placement surface 121 in the first state. A gap length (size) GP of the gap 300 is preferably, for example, 1 mm or less. As described above, when the exhauster 9 is open by the valve device 1, the gas GS1 is discharged. In this case, the gas GS1 passes through the gap 300.

However, in some cases, it may be difficult for the gap length GP to be constant at any location between the lower surface 143 of the ring part 142 and the placement surface 121, that is, the gap length GP may change in a circumferential direction of the ring part 142. The reason for this may include machinability accuracy of the cover member 140 and positioning accuracy of the cover member 140 in the first state. When the gap length GP changes in the circumferential direction of the ring part 142, a flow rate of the gas GS1 passing through the gap 300 may also change (differs) in the circumferential direction of the ring part 142, or a formation state of the thin film on the wafer W may not be uniform. Further, the smaller the gap length GP, the higher the flow rate of the gas GS1.

Therefore, the substrate processing apparatus 100 is configured to be capable of reducing such a phenomenon in which the formation state of the thin film becomes non-uniform. This configuration and operation will be described below. A method of obtaining the magnitude of the gap length GP is not particularly limited and may include a method of determining which degree of the gap length GP is obtained at which place of the ring part 142 by confirming the uniformity of the formation state of the thin film on the wafer W through previous film formation processing experiments.

As illustrated in FIG. 12, eight recesses 190 are provided in the sidewall portion 113 of the chamber 110. Each recess 190 is disposed below the transfer path 200 in communication with one exhauster 9. Each recess 190 includes a fan-shaped portion 191 that is fan-shaped in a plan view of the placement surface 121 viewed from above and a communicator 192 that extends linearly downward from the fan-shaped portion 191 to communicate with the exhauster 9. The fan-shaped portion 191 includes a chamber opening 193 that opens in a horizontal direction toward the stage 120 and has a fan shape in which the chamber opening 193 is more open than the opposite side. In this embodiment, the gap length GP of the gap 300 facing the fan-shaped portion 191 of each recess 190 is known in advance, and information about each gap length GP is stored in a storage 162 of the controller 160, which will be described later.

As described above, the substrate processing apparatus 100 includes the controller 160. As illustrated in FIG. 11, the controller 160 is communicably connected to each of the drivers 6 of the valve devices 1A to 1H. The controller 160 includes a CPU 161 and the storage 162. The storage 162 stores programs for independently controlling the drivers 6 of the valve devices 1A to 1H. The CPU 161 may execute programs stored in the storage 162.

As an example, it is assumed that the gap length GP in the state illustrated in FIG. 13 (hereinafter referred to as “gap length GP1”) is larger than the gap length GP in the state illustrated in FIG. 14 (hereinafter referred to as “gap length GP2”). In this case, the flow rate of the gas GS1 passing through a portion of the gap 300 having the gap length GP1 is slower than the flow rate of the gas GS1 passing through a portion of the gap 300 having the gap length GP2. Further, the gas GS1 passing through the portion having the gap length GP1 may be certainly directed toward the valve device 1G (see FIG. 13). This is because the fan-shaped portion 191 of the recess 190 on an upstream side of the valve device 1G prevents inflow of the gas GS1 into the other recesses 190 (valve device IF and valve device 1H) on both sides of the recess 190. In this way, the fan-shaped portion 191 functions as a guider that guides (directs) the gas GS1 to a predetermined recess 190. Similarly, the gas GS1 passing through the portion having the gap length GP2 may be certainly directed toward the valve device 1C (see FIG. 14).

In this state in which the flow rates of the gas GS1 are different from each other, the controller 160 controls the driver 6 of the valve device 1G to reduce the opening degree of the exhauster 9 by the valve device 1G and, simultaneously, controls the driver 6 of the valve device 1C to increase the opening degree of the exhauster 9 by the valve device 1C. Thus, the flow rate of the gas GS1 passing through the portion having the gap length GP1 is equal to the flow rate of the gas GS1 passing through the portion having the gap length GP2. As a result, the formation state of the thin film on the wafer W becomes uniform. As described above, the substrate processing apparatus 100 may adjust the opening degree of the exhauster 9 by each valve device 1 according to the size of the gap length GP. As a result, the flow rate of the gas GS1 passing through the gap 300 is constant at any location in the circumferential direction of the ring part 142, so that the formation state of the thin film formation may be uniform.

Although the exemplary embodiments of the present disclosure have been described above, the present disclosure is not limited to the embodiments described above, and various modifications and changes may be made within the scope and spirt of the present disclosure. For example, the valve device 1 is used in a semiconductor manufacturing process but is not limited thereto. Further, although the valve device 1 is disposed so that the flow path 10 is parallel to a vertical direction in each embodiment, the present disclosure is not limited thereto. The flow path 10 may be parallel to, for example, a horizontal direction. Further, although the seal member 20 is disposed in the valve body 2 in each embodiment, the seal member 20 is not limited thereto and may be disposed in, for example, the exhauster 9. Further, although the fluid passing through the flow path 10 is the gas GS1 in each embodiment, the fluid is not limited thereto and may be, for example, liquid. In addition, in each embodiment, the fluid passing through the flow path 10 flows from the first extension/contraction portion 4A to the second extension/contraction portion 4B but is not limited thereto. For example, the fluid may flow from the second extension/contraction portion 4B to the first extension/contraction portion 4A, that is, the fluid may flow backward.

According to the present disclosure in some embodiments, it is possible to increase a degree of freedom in layout when disposing a valve device, and suppress particles from adhering to a valve body while smoothly flowing a fluid with a simplified configuration.

What is claimed is:

1. A valve device, comprising:
a valve body configured to cause an opening through which a fluid passes to be in a closed state by moving close to the opening and cause the opening to be in an open state by moving away from the opening in the closed state;
a first extension/contraction portion formed in a cylindrical shape and configured to be extendible in a direction of a central axis of a first flow path according to movement of the valve body, an inner side of the first extension/contraction portion functioning as the first flow path through which the fluid passes;
a second extension/contraction portion disposed on one side of the first extension/contraction portion, formed in a cylindrical shape and configured to be extendible in the direction of the central axis of the first flow path according to the movement of the valve body, an inner side of the second extension/contraction portion functioning as the first flow path together with the first extension/contraction portion;
an intermediate portion disposed between the first extension/contraction portion and the second extension/contraction portion and configured to support the valve body; and
a driver connected to the intermediate portion on an outside of the first extension/contraction portion and the second extension/contraction portion and configured to drive the valve body so as to move the valve body together with the intermediate portion in the direction of the central axis of the first flow path and cause the opening to change between the open state and the closed state.

2. The valve device of claim 1, wherein the intermediate portion includes a supporter extending in the direction of the central axis of the first flow path and configured to support the valve body.

3. The valve device of claim 2, wherein the intermediate portion includes a ring part of a ring shape having a center at which the supporter is disposed, and a connector configured to connect the ring part and the supporter.

4. The valve device of claim 3, wherein the connector has a radial shape centered on the supporter.

5. The valve device of claim 1, wherein the valve body has a cylindrical shape disposed parallel to the central axis of the first flow path, and includes a first tapered portion having a tapered shape formed on a side of the opening and having an outer diameter gradually decreasing toward the side of the opening, and a second tapered portion formed on an opposite side to the first tapered portion and having an outer diameter gradually decreasing toward the opposite side to the first tapered portion.

6. The valve device of claim 5, wherein a top portion of the first tapered portion is rounded.

7. The valve device of claim 5, wherein the second tapered portion is smaller in a tapered angle than the first tapered portion.

8. The valve device of claim 5, wherein the fluid is discharged from the opening, and a second flow path on an upstream side of the opening has an inner diameter gradually increasing toward the upstream side, and
wherein a portion of the first tapered portion enters the opening that is in either the closed state or the open state.

9. The valve device of claim 5, wherein an edge of the opening has a flat surface perpendicular to the central axis of the first flow path, and
wherein a seal member of a ring shape is provided along a circumferential direction of the valve body between the first tapered portion and the second tapered portion, and configured to be in close contact with the flat surface when the opening is in the closed state.

10. The valve device of claim 1, wherein each of the first extension/contraction portion and the second extension/contraction portion has a bellows shape.

11. The valve device of claim 1, wherein the first extension/contraction portion and the second extension/contraction portion are made of a same metal material,
wherein the intermediate portion is made of a metal material different from the first extension/contraction portion and the second extension/contraction portion, and
wherein the first extension/contraction portion and the intermediate portion are connected to each other by welding, and the second extension/contraction portion and the intermediate portion are connected to each other by the welding.

12. The valve device of claim 1, wherein the driver is configured to adjust a separation distance of the valve body with respect to the opening in the open state.

13. The valve device of claim 12, wherein the driver includes a motor and a ball screw connected to the motor.

14. The valve device of claim 1, wherein an inert gas flow path through which an inert gas passes is provided inside the valve body, and
wherein the inert gas flow path includes a discharge port through which the inert gas is discharged radially into the first flow path.

15. The valve device of claim 14, wherein a seal member is provided in the valve body in close contact with an edge of the opening in the closed state, and
wherein the discharge port discharges the inert gas toward the seal member.

16. The valve device of claim 14, wherein the discharge port is provided on a side of the opening of the valve body.

17. The valve device of claim 1, further comprising a heater provided inside the valve body and configured to generate heat by being supplied with electric power.

18. The valve device of claim 17, wherein an electric power wiring is connected to the heater, and
a wiring storage is provided inside the valve body to store the electric power wiring.

19. The valve device of claim 1, further comprising: a guider configured to guide the valve body when the valve body moves.

20. The valve device of claim 19, further comprising: an outer cylindrical body configured to store the first extension/contraction portion, the second extension/contraction portion, and the intermediate portion, and
wherein the guider is disposed inside the outer cylindrical body.

21. The valve device of claim 20, wherein the guider is disposed between an outer peripheral portion of the intermediate portion and an inner peripheral portion of the outer cylindrical body, and includes a plurality of spheres configured to be rollable with the movement of the valve body.

22. The valve device of claim 19, further comprising: an outer cylindrical body configured to store the first extension/contraction portion, the second extension/contraction portion, and the intermediate portion, and
wherein the guider is disposed outside the outer cylindrical body.

23. The valve device of claim 22, wherein the driver includes a motor and a ball screw connected to the motor, and
wherein the guider includes a linear shaft disposed parallel to the ball screw and a linear bush configured to move on the linear shaft.

24. The valve device of claim 1, wherein the opening is an exhauster of a chamber in a depressurized state, and
wherein the valve device is attached to the exhauster.

25. A substrate processing apparatus for performing processing on a substrate, the substrate processing apparatus comprising:
a stage having a placement surface on which the substrate is placed;
a chamber configured to store the stage together with the substrate placed on the placement surface;
at least one exhauster connected to the chamber and configured to exhaust an interior of the chamber; and
a valve device connected to the exhauster and configured to open and close the exhauster,
wherein the valve device of claim 1 is used as the valve device.

26. The substrate processing apparatus of claim 25, wherein the stage is fixed to the chamber,
wherein the exhauster includes a plurality of exhausters disposed in a circumferential direction of the placement surface when viewed from a direction facing the placement surface, and
wherein the valve device is connected to each of the plurality of exhausters.

27. The substrate processing apparatus of claim 26, wherein the valve device includes a plurality of valve devices configured to be controlled independently of each other.

28. The substrate processing apparatus of claim 26, wherein the chamber includes a chamber opening formed to open in a horizontal direction toward the stage, and a recess formed to communicate with the exhauster at a position different from the chamber opening.

29. The substrate processing apparatus of claim 28, wherein the recess has a fan shape in which the chamber opening is open when viewed from a direction facing the placement surface.

30. The substrate processing apparatus of claim 28, wherein the chamber includes a loading/unloading port through which the substrate is loaded and unloaded in the horizontal direction, and
wherein the recess is located below a transfer path along which the substrate is transferred in the horizontal direction by passing through the loading/unloading port.

31. The substrate processing apparatus of claim 25, further comprising: a cover member provided to be movable into the chamber and configured to take a first state in which the cover member covers the substrate placed on the placement surface and a second state in which the cover member opens the substrate from the first state,
wherein the chamber includes a loading/unloading port through which the substrate is loaded and unloaded in a horizontal direction, and
wherein the cover member in the first state is located below a transfer path along which the substrate is transferred in the horizontal direction by passing through the loading/unloading port.

32. The substrate processing apparatus of claim 31, wherein the cover member includes a ring part provided to protrude downward and configured to surround the substrate in the first state, and
wherein a gap is formed between a lower surface of the ring part and the placement surface in the first state.

33. The substrate processing apparatus of claim 32, wherein an opening degree of the exhauster is adjusted by the valve device according to a size of the gap.

34. A method of manufacturing the valve device of claim 1, the method comprising:
a molding operation of integrally molding the valve body and the intermediate portion by an additive manufacturing method, and
a connection operation of connecting a molded body of the valve body and the intermediate portion molded in the molding operation, the first extension/contraction portion, and the second extension/contraction portion.
